(19) United States
(12) Patent Application Publication
(10) Pub. No.: US 2009/0246399 A1
(43) Pub. Date: Oct. 1, 2009

(54) METHOD FOR ACTIVATING REACTIVE OXYGEN SPECIES FOR CLEANING CARBON-BASED FILM DEPOSITION

(75) Inventors: Kamal Kishore Goundar, Yokohama (JP); Yamaguchi Masashi, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: ASM JAPAN K.K., Tokyo (JP)

(21) Appl. No.: 12/058,629

(22) Filed: Mar. 28, 2008

(51) Int. Cl. C23C 16/32; B08B 6/00; B05C 11/00

(52) U.S. Cl. 427/488; 134/1.1; 118/70

(57) ABSTRACT

A method of continuously forming carbon-based films on substrates includes: (i) forming a carbon-based film on a substrate in a reactor a pre-selected number of times; (ii) exciting an inert gas, an oxygen gas, and a nitrogen tri-fluoride gas to generate a plasma for cleaning; (iii) cleaning an inside of the reactor with the plasma after step (i) to remove particles accumulated during step (i) on the inside of the reactor.

### BACKGROUND OF THE INVENTION

1. Field of the Invention

The present invention relates generally to methods for operating a chemical vapor deposition (CVD) chamber, and more specifically, to methods for cleaning polymer based carbon-containing deposits from a CVD chamber with a reactive oxygen species.

2. Description of the Related Art

In the manufacturing of semiconductor devices, materials such as carbons are typically deposited on a substrate in a processing chamber. Plasma enhanced chemical vapor deposition (PECVD) method has been used in the deposition of these carbon materials. In accordance with PECVD, a substrate is placed in a vacuum deposition chamber equipped with a pair of parallel plate electrodes.

In a single-substrate processing apparatus, during CVD processing, a film is not only formed on the substrate but also on other regions of the chamber. Unwanted film on these regions produces particles which deposit on the substrate during CVD processing which as a result deteriorate the quality of the film on the substrate. Thus, the CVD chamber is cleaned periodically by using an in-situ cleaning process. Accumulation of adhesive products on surfaces of electrodes may affect plasma generation or distribution over a substrate and may cause damage to the electrodes. The materials deposited in these areas can affect the deposition rate from substrate to substrate and the uniformity of the deposition on the substrate.

Several methods for cleaning CVD chambers have been developed. For example, when fluorine doped SiO2 and SiN are deposited in a CVD chamber, the inner surface of the chamber can be cleaned by remote plasma cleaning. In that case, Argon gas is added as a feedstock to stabilize plasma discharge in a remote plasma chamber isolated from the CVD chamber. This technology is disclosed in U.S. Pat. No. 6,187,691, and U.S. Patent Publication No. 2002/0011210A. The following references also disclose chamber cleaning technologies. U.S. Pat. No. 6,374,831, U.S. Pat. No. 6,387,207, U.S. Pat. No. 6,329,297, U.S. Pat. No. 6,271,148, U.S. Pat. No. 6,347,636, U.S. Pat. No. 6,187,691, U.S. Patent Publication No. 2002/0011210A, U.S. Pat. No. 6,352,945, and U.S. Pat. No. 6,383,955. The disclosure of the foregoing references is herein incorporated by reference in their entirety, especially with respect to configurations of a reactor and a remote plasma reactor, and general cleaning conditions.

However, the above conventional methods are not effective in cleaning a carbon-based film such as the amorphous carbon film including diamond-like carbon film and the carbon polymer film described above, which have high carbon contents.

### SUMMARY OF THE INVENTION

During the process of depositing a carbon-based film on a substrate a pre-selected number of times, a carbon-based film is also deposited on areas other than the substrate such as an inner wall and a showerhead (an upper electrode). Upon completion of deposition of a carbon-based film on a substrate, the cleaning of the reactor is initiated. If an oxygen-containing gas or oxygen-based gas is used as a cleaning gas, because oxygen ions are negatively charged, a plasma sheath is formed on a cleaning target by oxygen plasma generation, inhibiting oxygen ions from reaching the cleaning target. Further, because the life of oxygen ions is short, they cannot reach locations in the reactor far from the place where oxygen ions are generated, resulting in insufficient cleaning at the locations. On the other hand a known remote plasma cleaning is a time consuming process. Remote plasma unit typically provides reactive species, such as a free radicals, at a flow rate and an intensity that do not result in level of free radicals sufficient to provide a reliable cleaning efficiency. As a result, contaminant particles are generated and accumulate on the inner wall and/or the showerhead, and then fall on a substrate surface during a deposition process.

In an aspect, the disclosed embodiments provide a method of continuously forming carbon-based films on substrates, comprising: (i) forming a carbon-based film on a substrate in a reactor a pre-selected number of times; (ii) exciting oxygen gas, and nitrogen fluoride gas, and inert gas to generate a plasma for cleaning; (iii) cleaning an inside of the reactor with the plasma to remove particles accumulated during step (i) on the inside of the reactor.

The above aspect includes, but is not limited to, the following embodiments:

In any of the foregoing embodiments, step (ii) may be conducted in the reactor or may be conducted in the reactor and in a remote plasma unit. The method may further comprise determining a priority area of cleaning inside the reactor prior to step (ii).

Step (iii) may comprise controlling pressure inside the reactor according to the priority area of cleaning.

In any of the foregoing embodiments, step (iii) may comprise controlling pressure inside the reactor in a range of about no control state to about 500 Pa.

In any of the foregoing embodiments, the method may further comprise selecting a cleaning gas including the oxygen gas, a nitrogen tri-fluoride gas as the nitrogen fluoride gas, and an inert gas such as Argon. Step (ii) may further compromise controlling a gap between and upper electrode and a lower electrode. Step (iii) may comprise controlling gap between the electrodes at about 10 mm to about 35 mm. In the above the oxygen gas may be O2 gas and the inert gas can be Argon. The fluorine containing gas is preferably nitrogen tri-fluoride.

In any of the foregoing embodiments, the carbon-based polymer film in step (i) may be a carbon polymer film formed by: (a) vaporizing a hydrocarbon-containing liquid monomer (C_{α}H_{β}X_{γ}, wherein α and β are natural numbers of 5 or more; γ is an integer including zero; X is O, N or F) having a boiling point of about 20° C. to about 350° C. which has no benzene structure; (b) introducing said vaporized gas into a CVD reaction chamber inside which a substrate is placed; and (c) forming a hydrocarbon-containing polymer film on said substrate by plasma polymerization of said gas.

In another aspect, the disclosed embodiments provide a method of self-cleaning a plasma reactor using a cleaning gas containing oxygen gas, nitrogen tri-fluoride and inert gas at a pre-selected pressure upon depositing a carbon-based film on a substrate a pre-selected number of times, comprising: (i) changing the cleaning gas and/or the pressure; the step of changing the cleaning gas comprising (a) increasing a flow rate of oxygen gas for increasing a ratio of an etching rate of a carbon polymer accumulated in the reactor.

The above aspect includes, but is not limited to, the following embodiments:

In any of the foregoing embodiments, in step (i), the plasma may be generated from the combination of oxygen gas, nitrogen tri-fluoride gas, and inert gas. The inert gas may be Argon.

In embodiments, the cleaning gas is preferably composed of oxygen gas such as O₂ gas, and fluorine containing gas such as nitrogen tri-fluoride. The cleaning gas is particularly effective on cleaning of a reactor for depositing carbon-based films. In embodiments, the flow rate ratio of (fluorine gas)/(oxygen gas)/(inert gas) may be (1−50)/(100)/(0−1000), preferably (3−15)/(100)/(70−700). In embodiments, the ratio of (fluorine gas)/(oxygen gas) may be 0.2 or less (including 0.1, 0.07, 0.05, 0.03, and values between any two numbers of the foregoing, preferably 0.1 or less or 0.05 or less but more than 0.01). When a small amount of nitrogen tri-fluoride is added, the nitrogen tri-fluoride can synergistically and surprisingly effectively activate oxygen gas for cleaning. The etching rate can increase more than two-fold, preferably 5-fold, more preferably 10-fold as compared with the case where no nitrogen tri-fluoride is added (e.g., 400 nm/min or higher, 1000 nm/min or higher, 2000 nm/min or higher). In an embodiment, no gas other than the inert gas, oxygen gas, and nitrogen tri-fluoride gas is used. In embodiments, a flow rate of the oxygen gas may be set at a value which is 10% to 60% of total flow gas flow rates of the rare inert gas, the oxygen gas, and fluorine based gas. Furthermore, in embodiments, a flow rate of the fluorine gas may be set at a value which is 0.5% to 10% of total flow gas flow rates of the rare inert gas, the oxygen gas, and fluorine based gas.

In all of the aforesaid aspects and embodiments, any element used in an aspect or embodiment can interchangeably or additionally be used in another aspect or embodiment unless such a replacement is not feasible or causes adverse effect. Furthermore, reactors can be programmed to conduct any of the foregoing methods or processes.

For purposes of summarizing aspects of the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description of the preferred embodiments which follow.

### BRIEF DESCRIPTION OF THE DRAWINGS

These and other features of this invention will now be described with reference to the drawings of preferred embodiments which are intended to illustrate and not to limit the invention. The drawings are oversimplified for illustrative purposes and are not to scale.

FIG. 1 is a schematic view showing an example of a CVD apparatus for forming a polymer hard mask provided with a remote plasma unit which can be used in an embodiment of the present invention.

FIG. 2 is a schematic view showing an example of a CVD apparatus forming a polymer hard mask provided with a remote plasma unit which can be used in an embodiment of the present invention.

FIG. 3 is a graph showing the relationship between cleaning rate and O2 flow rate according to embodiments of the present invention (Example 1).

FIG. 4 is a graph showing the results of the etching rate when the cleaning gas composed of oxygen with low flow of nitrogen tri-fluoride gas flow according to embodiments of the present invention (Example 2).

FIG. 5 is a graph showing the relationship between the etching rate and the gas ratio of nitrogen tri-fluoride to the total gas. (Example 3).

### DETAILED DESCRIPTION OF THE PREFERRED EMBODIMENT

The present invention will be explained in detail with reference to preferred embodiments. However, the preferred embodiments are not intended to limit the present invention.

In an embodiment, a method of continuously forming carbon-based films on substrates, comprises: (i) forming a carbon-based film on a substrate in a reactor a pre-selected number of times; (ii) exciting a inert gas, an oxygen gas, and a nitrogen tri-fluoride gas to generate a plasma for cleaning; (iii) cleaning an inside of the reactor with the plasma to remove particles accumulated during step (i) on the inside of the reactor.

Step (ii) may be conducted in the reactor or may be conducted in the reactor and in a remote plasma unit. The method may further comprise determining a priority area of cleaning inside the reactor prior to step (ii). Step (iii) may comprise controlling pressure inside the reactor according to the priority area of cleaning.

Step (iii) may comprise controlling pressure inside the reactor at about no control state to about 500 Pa.

The method may further comprise selecting a cleaning gas including the oxygen gas, nitrogen tri-fluoride gas, and an inert gas such as Argon. Step (ii) may further compromise controlling a gap between and upper electrode and a lower electrode. Step (iii) may comprise controlling a gap between the electrodes at about 10 mm to about 35 mm. In the above, the oxygen gas may be O2 gas and the inert gas can be Argon. The fluorine containing gas may be nitrogen tri-fluoride.

In an embodiment, a method of continuously forming carbon-based films on substrates, comprises: (i) forming a carbon-based film on a substrate in a reactor a pre-selected number of times; (ii) exciting a inert gas, an oxygen gas, and a nitrogen tri-fluoride gas to generate a plasma for cleaning; (iii) cleaning an inside of the reactor with the plasma to remove particles accumulated during step (i) on the inside of the reactor.

In any of the aforesaid embodiments, in step (ii), the oxygen gas and the fluorine based gas may be used as a required gas. The oxygen gas may be O2 gas. In any of the aforesaid embodiments, the inert gas may be any one or more of Ar gas, He gas, Ne gas, Kr gas, and Xe gas.

In any of the aforesaid embodiments, in step (ii), a flow rate of the oxygen gas may be set at 100 to 5,000 sccm (including 1,000 sccm, 2,000 sccm, 3,000 sccm, and values between any two numbers of the foregoing), a flow rate of the inert gas may be set at 1,000 to 10,000 sccm (including 3,000 sccm, 4,000 sccm, 5,000 sccm, and values between any two numbers of the foregoing), rate of the fluorine gas may be set at 10 to 500 sccm (including 25 sccm, 50 sccm, 100 sccm, 200 sccm, 300 sccm, and values between any two numbers of the foregoing) in embodiments.

In embodiments, the flow rate ratio of (fluorine gas)/(oxygen gas)/(inert gas) may be (1−50)/(100)/(0−1000), preferably (3−15)/(100)/(70−700). In embodiments, a flow rate of the oxygen gas may be set at a value which is 10% to 60% of total flow gas flow rates of the inert gas, the oxygen gas, and fluorine based gas. Furthermore, in embodiments, a flow rate of the fluorine gas may be set at a value which is 0.5% to 10% of total flow gas flow rates of the rare inert gas, the oxygen gas, and fluorine based gas.

In any of the aforesaid embodiments, in steps (i) to (iii), a susceptor on which the substrate is placed may be controlled at a temperature of 200° C. or higher (e.g., 340° C. or higher).

In any of the aforesaid embodiments, the carbon-based polymer film in step (i) may be a carbon polymer film formed by: (I) vaporizing a hydrocarbon-containing liquid monomer (C_{α}H_{β}X_{γ}, wherein α and β are natural numbers of 5 or more; γ is an integer including zero; X is O, N or F) having a boiling point of about 20° C. to about 350° C. which is not substituted by a vinyl group or an acetylene group; (II) introducing said vaporized gas into a CVD reaction chamber inside which a substrate is placed; and (III) forming a hydrocarbon-containing polymer film on said substrate by plasma polymerization of said gas. In an embodiment, the liquid monomer technology disclosed in U.S. Patent publication No. 2006/0084280 and No. 2007/0218705 can be used, the disclosure of which is herein incorporated by reference in their entirety.

In the present disclosure including the above, the ranges described may include or exclude the endpoints in embodiments.

An embodiment of the present invention provides a method of self-cleaning a plasma reactor using a cleaning gas containing oxygen gas, fluorine based gas, and inert gas at a pre-selected pressure upon depositing a carbon-based film on a substrate a pre-selected number of times. In an embodiment, the cleaning of the reactor can be conducted every after a given number of substrates (e.g., 1-50 substrates, typically 4-25 substrates) are processed. The frequency of cleaning can be determined depending on the amount of unwanted film accumulated inside the reactor during the deposition process, the amount of particles generated by the cleaning itself, etc.

In another embodiment it comprises: (i) introducing inert gas to a remote plasma unit, followed by igniting plasma; (ii) upon the ignition, introducing oxygen gas together with inert gas and flowed by the fluorine based gas to the remote plasma unit; (iii) exciting the oxygen and fluorine gas together with the inert gas via plasma in the remote plasma unit; (iv) introducing the excited inert gas and the oxygen and fluorine gas to the reactor, thereby performing self-cleaning of the reactor. The type and the flow rate of the rare gas and the oxygen gas can be those described earlier or anywhere in the present disclosure.

The present invention will be described in detail with reference to other embodiments. The present invention, however, is not limited to these embodiments. Additionally, a requirement in an embodiment is freely applicable to other embodiments, and requirements are mutually replaceable unless special conditions are attached.

The reactor may be a capacitively-coupled plasma apparatus wherein a showerhead which can serve as an upper electrode and a susceptor which serves as a lower electrode are disposed in parallel to each other. The reactor may be a PECVD apparatus, HDP-CVD apparatus, ALD apparatus, etc. in which unwanted particles are accumulated on the showerhead and the inner wall during deposition of film of interest on a substrate.

The film deposited on a substrate in the reactor, upon deposition of which the cleaning inside the reactor of the embodiments is conducted, is a carbon-based film which may be defined as a film containing 30% or more carbon (typically 30% to 80%, preferably 40% to 60%) per mass of the entire compositions in an embodiment. In another embodiment, the carbon-based film may be defined as a film formed with a carbon skeleton. In another embodiment, the carbon-based film may be defined as a film having a general formula CxHy (x, y are an integer of 2 or greater). The carbon-based film includes, but is not limited to, a nano-carbon polymer film disclosed in U.S. Patent Publication No. 2006/0084280 and No. 2007/0218705 (the disclosure of which is herein incorporated by reference in their entirety), and an amorphous carbon film (including diamond-like carbon film) disclosed in U.S. Patent Publications No. 2003/0091938 and No. 2005/0112509, U.S. Pat. No. 5,470,661, and U.S. Pat. No. 6,428,894 (the disclosure of which is herein incorporated by reference in their entirety).

For example, as disclosed in U.S. Patent Publication No. 2006/0084280 mentioned above, a nano-carbon polymer film can be formed a method which comprises the steps of vaporizing a hydrocarbon-containing liquid monomer (C_{α}H_{β}X_{γ}, wherein α and β are natural numbers of 5 or more; γ is an integer including zero; X is O or N) having a boiling point of 20° C.-350° C. which is not substituted by a vinyl group or an acetylene group, introducing the vaporized gas into a CVD reaction chamber inside which a substrate is placed, and forming a hydrocarbon-containing polymer film on the substrate by plasma polymerizing the gas. The substrate is, for example, a semiconductor device substrate. In the above method, the liquid monomer may be introduced into a heater disposed upstream of the reaction chamber and vaporized. Additionally, the liquid monomer may be flow-controlled by a valve upstream of the heater, and introduction of the liquid monomer into the heater may be blocked by a shutoff valve disposed between the flow control valve and the heater and kept at 80° C. or lower or at a temperature lower than that of heating/vaporization by approximately 50° C. or more except when a film is formed. Or, the liquid monomer may be flow-controlled by a valve disposed upstream of the heater and kept at 80° C. or lower or at a temperature lower than that of heating/vaporization by approximately 50° C. or more, and at the same time introduction of the liquid monomer into the heater may be blocked except when a film is formed.

Further, as disclosed in U.S. Patent Publication No. 2006/0084280, usable liquid organic monomers for a nano-carbon polymer film are as follows:

As a liquid organic monomer, cyclic hydrocarbon can be used. The cyclic hydrocarbon may be substituted or non-substituted benzene. Further, the substituted or non-substituted benzene may be C₆H₆₋ₙRₙ (wherein n, 0, 1, 2, 3); R may be independently —CH₃ or —C₂H₅. The liquid monomer may be a combination of two types or more of substituted or non-substituted benzene. In the above, the substituted benzene may be any one or more of 1,3,5-trimethylbenzene, o-xylene, m-xylene or p-xylene; in addition to a benzene derivative, the cyclic hydrocarbon may be any one or more of cyclohexane, cyclohexene, cyclohexadiene, cyclooctatetraene, cyclopentane, and cyclopentene. The liquid monomer may be linear hydrocarbon, and the linear hydrocarbon may also be any one or more of pentane, iso-pentane, neo-pentane, hexane, 1-pentene, 1-hexene, 1-pentyne, and isoprene.

As a specific example, C₆H₃(CH₃)₃ (1,3,5-trimethylbenzene (TMB); boiling point of 165° C.) or C₆H₄(CH₃)₂ (dimethylbenzene (xylene); boiling point of 144° C.) can be mentioned. In addition to the above, as liner alkane (CₙH₂₍ₙ₊₁₎), pentane (boiling point of 36.1° C.), iso-pentane (boiling point of 27.9° C.) or neo-pentane (boiling point of 9.5° C.), wherein n is 5, or hexane (boiling point: 68.7° C.) or isoprene (boiling point: 34° C.), wherein n is 6, can be used singly or in any combination as a source gas.

Additionally, a liquid organic monomer is a hydrocarbon-containing liquid monomer (C_{α}H_{β}X_{γ}, wherein α and β are natural numbers of 5 or more; γ is an integer including zero; X is O, N or F) having a boiling point of room temperature or higher (e.g., approximately 20° C.-approximately 350° C.). Using this monomer, a hard mask is formed. Preferably, the carbon number is 6-30; the carbon number is 6-12. In this case as well, the liquid monomer is cyclic hydrocarbon, and the cyclic hydrocarbon may also be substituted or non-substituted benzene. Further, the substituted benzene or the non-substituted benzene may be C₆H₆₋ₙRₙ (wherein n is 0, 1, 2, or 3); R may be independently —CH₃, —C₂H₅, or —CH═CH₂. Additionally, the liquid monomer is a combination of two types or more of the non-substituted benzene.

In the above, the substituted benzene may be any one of 1,3,5-trimethylbenzene, o-xylene, m-xylene, or p-xylene; In addition to benzene derivatives, the cyclic hydrocarbon may be any one of cyclohexene, cyclohexadiene, cyclooctatetraene. Additionally, it may be linear hydrocarbon; the linear hydrocarbon may be pentane, iso-pentane, neo-pentane, hexane, 1-pentene, 1-hexene, 1-pentyne, and/or isoprene.

Additionally, a reaction gas composed of only the liquid monomer may be used. Specifically, C₆H₅(CH═CH₂) (vinylbenzene (styrene); boiling point of 145° C.) can be mentioned. In addition to this, as liner alkene (CₙHₙ (n=5)), 1-pentene (boiling point of 30.0° C.); or as liner alkyne (CₙH₂₍ₙ₋₁₎ (n=5), 1-pentyne (boiling point of 40.2° C.), etc. can be used singly or in any combination as a source gas.

In the disclosed embodiments, the cleaning of the reactor can be remote plasma cleaning. General methods of chamber cleaning are disclosed in U.S. Pat. No. 6,187,691, U.S. Patent Publication No. 2002/0011210A, U.S. Pat. No. 6,374,831, U.S. Pat. No. 6,387,207, U.S. Pat. No. 6,329,297, U.S. Pat. No. 6,271,148, U.S. Pat. No. 6,347,636, U.S. Pat. No. 6,187,691, U.S. Patent Publication No. 2002/0011210A, U.S. Pat. No. 6,352,945, and U.S. Pat. No. 6,383,955, for example, the disclosure of which is herein incorporated by reference in their entirety.

During the process of depositing a carbon-based film on a substrate a pre-selected number of times, a carbon-based film is also deposited on areas other than the substrate such as an inner wall and a showerhead (an upper electrode). Upon completion of deposition of a carbon-based film on a substrate, the cleaning of the reactor is initiated.

If an oxygen-containing gas or oxygen-based gas is used as a cleaning gas, because oxygen ions are negatively charged, a plasma sheath is formed on a cleaning target by oxygen plasma generation, inhibiting oxygen ions from reaching the cleaning target. Further, because the life of oxygen ions is short, they cannot reach locations in the reactor far from the place where oxygen ions are generated, resulting in insufficient cleaning at the locations. On the other hand a known remote plasma cleaning is a time consuming process. Remote plasma unit typically provides reactive species, such as a free radicals, at a flow rate and an intensity that do not result in level of free radicals sufficient to provide a reliable cleaning efficiency. As a result, contaminant particles are generated and accumulate on an inner wall or the showerhead, and then fall on a substrate surface during a deposition process. Furthermore, if a fluorine-containing gas such as NF₃, C₂F₆, and/or C₃F₈, is used as a cleaning gas in a conventional manner, fluorine binds to hydrogen present in the carbon-based film during a cleaning process, thereby generating HF which is likely to cause erosion to a showerhead or susceptor made of aluminum or its alloy. Consequently, contaminant particles are generated and accumulate on an inner wall or the showerhead, and then fall on a substrate surface during a deposition process. The above theories are not intended to limit the present invention.

In an embodiment of the present invention, a carbon-based film can effectively be removed using high concentration oxygen gas and low flow fluorine based gas incorporating with inert gas. When using high ratio oxygen gas and low flow fluorine gas as a cleaning gas, C and H in the carbon-based film (e.g., C:H=50%:50%) react with 0 and F that generates CO₂, COF₂ and H₂O which are discharged from the reactor to an exhaust system. These species are not likely to cause erosion to electrodes, thereby suppressing generation of contaminant particles.

When oxygen gas is added to fluorine gas, a plasma can be more stabilized and distributed widely inside the reactor, thereby more uniformly supplying an etchent (etching agent) to a wide area of the reactor. As a result, it is possible to increase a cleaning rate without causing damage to the electrodes. A ratio of oxygen gas to fluorine gas may be 100:0 to 0:100 including 100:20, 100:10, 100:5, 100:2.5, and ranges between any two numerals of the foregoing. In general low flow of fluorine is preferable for higher cleaning efficiency. However, the ratio can be selected depending on a priority or target area of cleaning in the cleaning process. If priority is given to electrodes for cleaning, the ratio may be set high, and if priority is given to an inner wall of the reactor, the ratio may be set low. For example, if the deposition temperature is relatively low, accumulation of more particles on the electrodes and the inner wall of the reactor occurs, and if the deposition temperature is relatively high, accumulation of less particles occurs. It is possible to determine in advance through experiments which section of the reactor needs to be targeted more than other sections for cleaning.

In the above embodiments and embodiment described below, the oxygen gas is preferably O₂ gas. Fluorine gas is preferably nitrogen tri-fluoride.

In embodiments, the flow rate ratio of (fluorine gas)/(oxygen gas)/(inert gas) may be (100)(1−100)/(0−100), preferably (100)/(20−50)/(0.1−25). In embodiments, a flow rate of the oxygen gas may be set at a value which is 10% to 60% of total flow gas flow rates of the rare inert gas, the oxygen gas, and fluorine based gas. Furthermore, in embodiments, a flow rate of the fluorine gas may be set at a value which is 0.5% to 10% of total flow gas flow rates of the rare inert gas, the oxygen gas, and fluorine based gas.

In the present disclosure where conditions and/or structures are not specified, the skilled artisan in the art can readily provide such conditions and/or structures, in view of the present disclosure, as a matter of routine experimentation. Further, the disclosure of U.S. Patent Publication No. 2007/0248767 can be used in embodiments of the present invention, the disclosure of which is herein incorporated by reference in their entirety.

The present invention will be explained with reference to preferred embodiment and drawings. The preferred embodiments and drawings are not intended to limit the present invention. Also, in the present disclosure, the numerical numbers applied in embodiments can be modified by a range of at least ±50% in other embodiments, and the ranges applied in embodiments may include or exclude the endpoints.

Nano-Carbon Polymer Formation

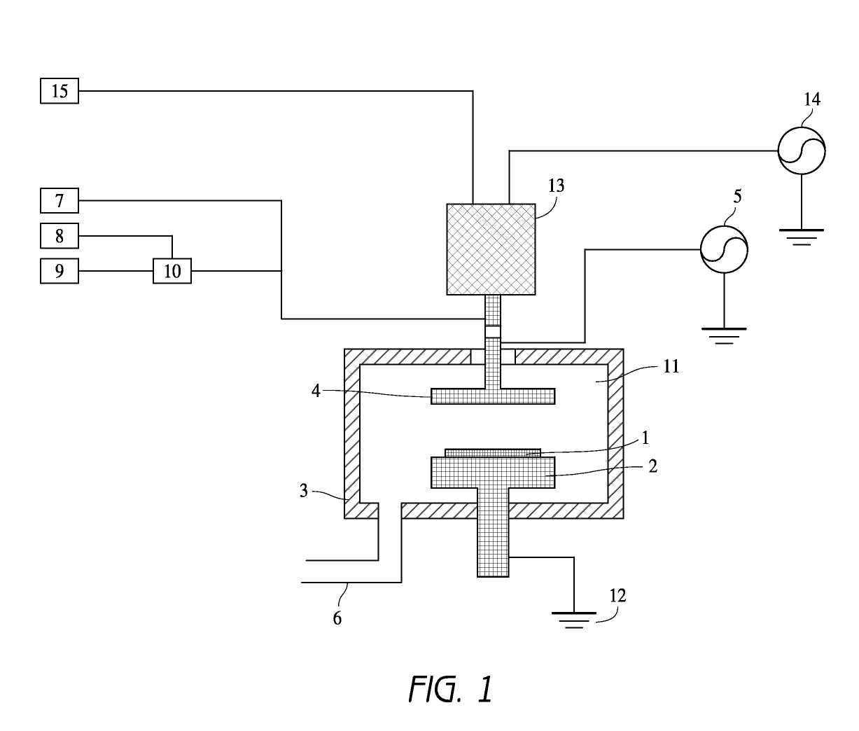

FIG. 1 is a schematic view of an apparatus combining a vaporizer and a plasma CVD reactor, which can be used in the embodiments. An apparatus which can be used in the present invention is not limited to an example shown in FIG. 1. The skilled artisan will appreciate that the apparatus includes one or more controller(s) (not shown) programmed or otherwise configured to cause the deposition and reactor cleaning processes described elsewhere herein to be conducted. The controller(s) will communicated with the various power sources, heating systems, pumps, robotics and gas flow controllers or valves of the reactor, as will be appreciated by the skilled artisan.

In this example, by providing a pair of electrically conductive flat-plate electrodes 4, 2 in parallel and facing each other inside a reaction chamber 11, applying power from an RF power source 5 to one side, and electrically leading to ground 12 the other side, plasma is excited between the electrodes. A temperature regulator is provided in a lower stage 2, and a temperature is kept constantly at a given temperature in the range of 0° C.-650° C. to regulate a temperature of a substrate 1 placed thereon. An upper electrode 4 serves as a shower plate as well, and reaction gas is introduced into the reaction chamber 11 through the shower plate. Additionally, in the reaction chamber 11, an exhaust pipe 6 is provided through which gas inside the reaction chamber 11 is exhausted.

A vaporizer 10 which vaporizes a liquid organic monomer has an inlet port for a liquid and an inlet port for an inert gas in an embodiment and comprises a mixing unit for mixing these gases and a unit for heating the mixture. In the embodiment shown in FIG. 1, an inert gas is introduced from an inert gas source in communication with an inert gas flow-controller 8 to the vaporizer 10; and a liquid monomer is introduced from a liquid monomer source in communication with a liquid monomer flow-controller 9 into the vaporizer 10. A heating temperature of the liquid monomer flow-controller 9 and the liquid source piping between the liquid monomer flow-controller 9 and the vaporizer 10 is determined based on characteristics of a liquid source; the temperature is kept in the range of 0° C.-350° C. in this embodiment. A heating temperature of a vaporizer 10 is also determined based on characteristics of a liquid source; the temperature is kept in the range of 0° C.-350° C. in this embodiment. In an embodiment, the liquid monomer includes a polymeric liquid. In that case, the temperature should be kept low. Vaporized gas is introduced into the reactor through gas piping. Additionally, the embodiment shown in FIG. 1 is designed to be able to introduce an additive gas from an additive gas source in communication with a gas flow-controller 7 into the reactor. Additionally, an inert gas can also be introduced into the reactor without passing through the vaporizer 10. The number of the gas flow-controller 7 is not limited to one, but can be provided appropriately to meet the number of gas types used.

The piping introducing the gas from the vaporizer to the reactor and a showerhead unit in an upper portion of the reactor are heated/temperature-controlled at a given temperature in the range of 30° C.-350° C. by a heater and their outer side is covered by an insulating material.

The apparatus shown in FIG. 1 is provided with a remote plasma gas source in communication with a remote plasma unit 13 to which given gas species are supplied a given flow rate from a gas flow mass control unit 15. RF power is applied to the remote plasma unit from a remote plasma power source 14, thereby igniting plasma and generating plasma for cleaning. Generated plasma and radicals are introduced to the reactor 11 via an upper part, thereby conducting cleaning of the reactor. In an embodiment, more than one gas flow mass control unit 15 can be used and suitably arranged depending on the type of gas, etc.

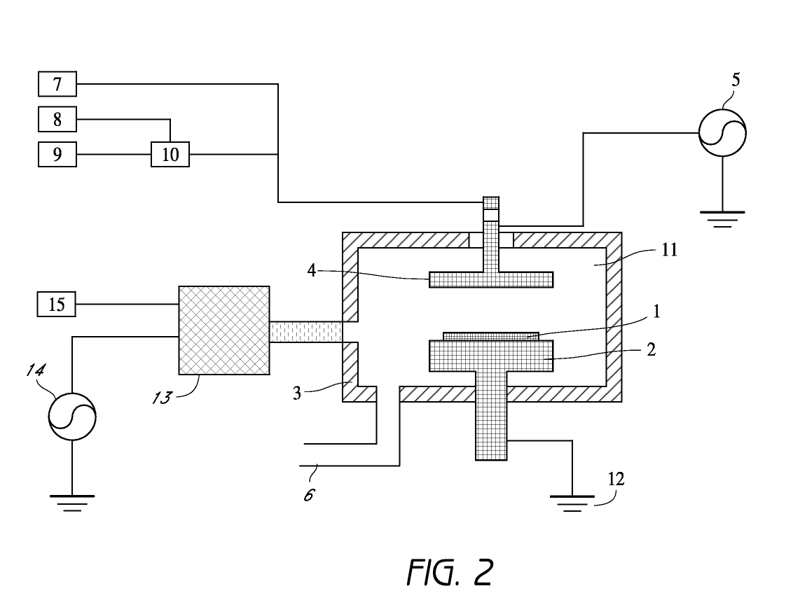

Further, the remote plasma unit 13 can be disposed on a side of the reactor as shown in FIG. 2. As shown in FIGS. 1 and 2, the remote plasma unit 13 need not be disposed at an upper part of the reactor but can be disposed at various locations.

Deposition conditions: Deposition conditions in the examples are as follows: Eagle®12 (ASM Japan) possessing a basic structure shown in FIG. 1 was used as a reactor. Additionally, in the case of these examples, although a liquid monomer was flow-controlled by a flow control unit in a liquid phase, an amount of gas introduced into a reactor was obtained by molar conversion from the flow rate of the liquid.

Reactor Settings:

Temperature of upper electrode (shower plate): 180° C.

Size of shower plate: φ325 mm

(Size of substrate: φ300 mm)

Susceptor temperature: 340° C.

Vaporizer: Vaporizing unit temperature: 40° C.

Controlled temperature of gas inlet piping: 100° C.

Gap between shower plate and susceptor: 16 mm

Process Conditions:

Precursor: Cyclopentene: 200 sccm

He supplied to vaporizer: 500 sccm

Ar supplied to the reactor: 1700 sccm

Process gas He supplied to the reactor: 1300 sccm

RF Power (13.56 MHz): 2050 W

Pressure: 733 Pa

Deposition time: 19 sec

Deposited Film Properties:

Thickness: 200 m

Reflective Index (n) @633 nm: 1.90

Extinction Coefficient (k) @633 nm: 0.09

Stress: −276 MPa

After depositing a nano-carbon polymer film on a semiconductor substrate, cleaning egan using a remote plasma unit under respective conditions described blow.

### Example 1

As a cleaning gas, O₂ gas was used. Ar gas was used for igniting plasma at the remote plasma unit. It took about 5 sec to ignite plasma. After ignition Ar flow was increased to the set point and supplied to the remote plasma unit. Cleaning conditions in this example and cleaning results are shown as follows. A cleaning rate was evaluated based on an etching rate on the carbon-based polymer film deposited on the substrate. In the examples, the etching rates were treated as cleaning rates.

Cleaning Conditions:

Gap between shower plate and susceptor: 25 mm

Susceptor temperature: 340° C.

Ar gas supplied to the remote plasma unit: 5,000 sccm

O₂ gas supplied to the remote plasma unit: 1,000, 1,500, 2,000 sccm

No fluorine-containing gas supplied to the remote plasma unit

Cleaning time: 20 sec

Cleaning Rates:

17.9 nm/min at 1,000 sccm of O₂

22.8 nm/min at 1,500 sccm of O₂

24.0 nm/min at 2,000 sccm of O₂

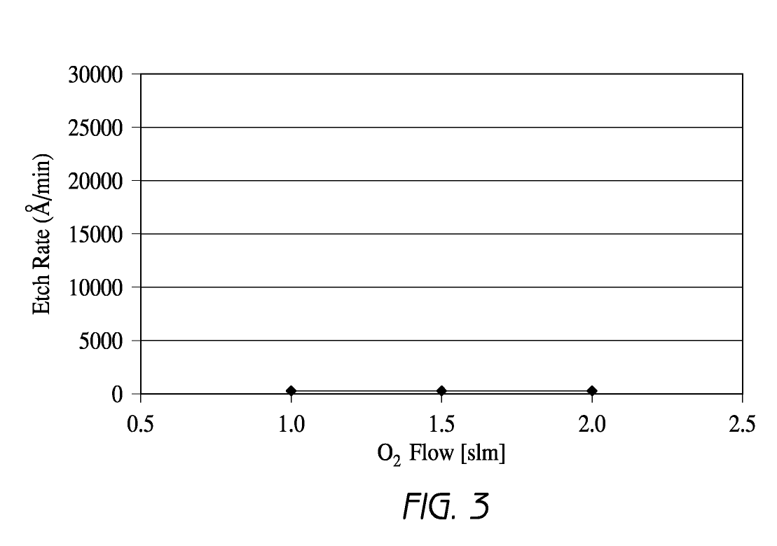

FIG. 3 shows the results when the cleaning gas was composed of high-flow oxygen and no flow of nitrogen tri-fluoride. Even though the flow of oxygen gas was increased, the cleaning rate (ER: etching rate) was remained low.

### Example 2

Under the same conditions as in Example 1 except that nitrogen tri-fluoride gas was continuously supplied to the remote plasma unit at a constant rate after the ignition. A cleaning rate (etching rate) was evaluated in the same way as in Example 1.

Cleaning Conditions:

Gap between shower plate and susceptor: 25 mm

Susceptor temperature: 340° C.

Ar gas supplied to the remote plasma unit: 5,000 sccm,

Nitrogen tri-fluoride gas supplied to the remote plasma unit: 100 sccm,

O₂ gas supplied to the remote plasma unit: 1,000 scc, 1,500 sccm, 2,000 sccm

Cleaning time: 20 sec

Cleaning Rates:

325 nm/min at nitrogen tri-fluoride 100 sccm, 1,000 sccm of O₂,

1453 nm/min at nitrogen tri-fluoride 100 sccm, 1,500 sccm of O₂

2172 nm/min at nitrogen tri-fluoride 100 sccm, 2,000 sccm of O₂

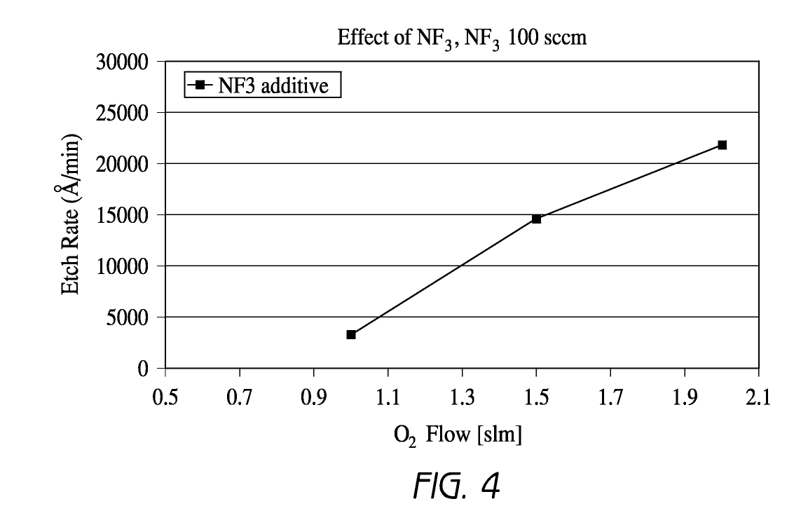

FIG. 4 shows the surprising results of adding nitrogen tri-fluoride gas to oxygen gas flow. As compared with Example 1, when nitrogen tri-fluoride was added to oxygen gas at a ratio of nitrogen tri-fluoride/oxygen gas of 0.05 to 0.1, the etching rate became about twenty to one hundred times greater than the case where no nitrogen tri-fluoride was added. The effect of nitrogen tri-fluoride was more significant when the oxygen gas flow was higher.

### Example 3

Under the same conditions as in Example 2 except that the flow rate of nitrogen tri-fluoride gas was changed while the flow rate of O₂ and Argon gas was constant. A cleaning rate (etching rate) was evaluated in the same way as in Example 1.

### Cleaning Conditions:

Gap between shower plate and susceptor: 25 mm

Susceptor temperature: 340° C.

Ar gas supplied to the remote plasma unit: 5,000,

O₂ gas supplied to the remote plasma unit: 2,000 sccm

nitrogen tri-fluoride gas supplied to the remote plasma unit: 100 sccm, 200 sccm, 300 sccm, 400 sccm

Cleaning time: 20 sec

Cleaning Rates:

214 nm/min at 400 sccm of nitrogen tri-fluoride

321 nm/min at 300 sccm of nitrogen tri-fluoride

1278 nm/min at 200 sccm of nitrogen tri-fluoride

2172 nm/min at 100 sccm of nitrogen tri-fluoride

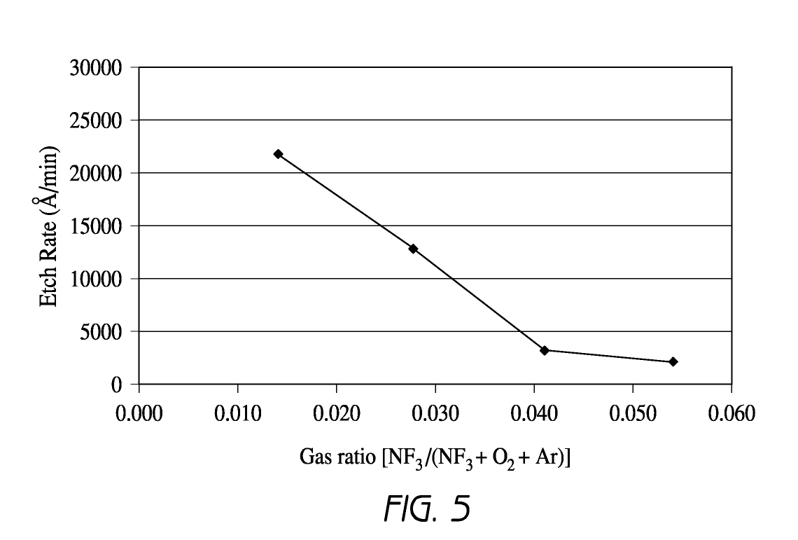

FIG. 5 shows the results of the gas ratio of nitrogen tri-fluoride gas to the total gas flow (nitrogen tri-fluoride, argon, oxygen). As for the ratio of nitrogen tri-fluoride/oxygen, when the ratio was 0.1 or less (preferably 0.05 or less), the increase of etching rate became significant. As for the ratio of nitrogen tri-fluoride/total gas, when the ratio was about 0.028 or less (preferably 0.014 or less), the increase of etching rate became significant.

As can be seen from Example 1 when only O₂ gas was used as a cleaning gas, no significant change in the cleaning performance was observed. However, when a small amount of nitrogen tri-fluoride gas was added at a flow rate of 100 sccm to the cleaning gas, the cleaning rate was significantly increased to 2172 nm/min at an O₂ flow rate of 2,000 sccm (Example 2).

Further, as shown in Example 2, when the flow rate of oxygen gas was increased from 1,000 sccm to 2,000 sccm at a constant nitrogen tri-fluoride gas flow rate of 100 sccm, the cleaning rate was increased by about 200% to 2172 nm/min. Thus, it can be understood that high O₂ flow rates can significantly increase the cleaning rates.

However, upper limits of O₂ flow rates and Ar flow rates exist depending on the controllable input power ranges of the remote plasma unit, the controllable pressure ranges of the reactor, etc. The cleaning efficiency is as a function of quantity of supplied cleaning gas, applied input power for cleaning, and pressure during cleaning. In the case of remote plasma cleaning, the quantity of supplied gas is correlated to the applied input power. However, the remote plasma unit may have an upper limit of the applied input power such as 2.9 kW, and thus, naturally, an upper limit is imposed on the quantity of supplied gas. Further, when the pressure is low, excited species (radicals) have less chances to collide with unexcited species (gas), thereby increasing the cleaning efficiency. However, it is difficult to maintain low pressure when significant quantity of cleaning gas is supplied even though a high power vacuum pump is used. Thus, an upper limit is imposed on the quantity of supplied gas.

Further, as shown in Example 3, the ratio of the nitrogen tri-fluoride gas is an important factor to improve the cleaning efficiency. Thus, it can be understood that at a constant flow of O₂ and Ar flow, addition of small amount of nitrogen tri-fluoride rates can significantly increase the cleaning rates.

When in-situ cleaning was conducted using O₂ gas as a cleaning gas, a cleaning rate was about 12.0 nm/min in an embodiment. Further, the O₂ gas in-situ cleaning was applied to a reactor after depositing a carbon-containing film having a thickness of 200 nm, it took about 1,000 seconds. However, when remote plasma cleaning was conducted using 2 slm of O₂ gas, 5 slm of Ar, and 0.1 slm of nitrogen tri-fluoride gas at a pressure of 300 Pa, it took as short a time period as 45 seconds. As a result, productivity per one hour was increased by 50%. Further, ion bombardment between the electrodes was suppressed, thereby prolonging the replacement life of the electrodes.

The present invention includes the above mentioned embodiments and other various embodiments including the following:

1) A method of continuously forming carbon-based films (or carbon-containing films or carbonaceous films) on a substrate, comprising:

(i) forming a carbon-based film on a substrate in a reactor a pre-selected number of times;

(ii) exciting oxygen gas, nitrogen tri-fluoride gas, and an inert gas such as Ar to generate a plasma for cleaning;

(iii) cleaning an inside of the reactor with the plasma to remove particles accumulated during step (i) on the inside of the reactor.

2) The method according to item 1, wherein step (ii) is conducted in the reactor and/or a remote plasma unit.

3) The method according to item 1 or 2, wherein the inert gas is one or more types of gas.

4) The method according to item 3, wherein the inert gas is Ar and one or more types of other gas.

5) The method according to any one of items 1 to 4, wherein the oxygen gas is O₂ gas.

6) The method according to any one of items 1 to 5, wherein a flow rate of the oxygen gas is no less than 10 sccm and no more than 10,000 sccm.

7) The method according to item 6, wherein a flow rate of the oxygen gas is no less than 100 sccm and no more than 5,000 sccm.

8) The method according to any one of items 1 to 7, wherein a flow rate of the nitrogen tri-fluoride gas is no less than 1 sccm and no more than 5,000 sccm.

9) The method according to any one of items 1 to 8, wherein a flow rate of the nitrogen tri-fluoride gas is no less than 5 sccm and no more than 1,000 sccm.

10) The method according to any one of items 1 to 9, wherein a flow rate of the nitrogen tri-fluoride gas is no less than 10 sccm and no more than 500 sccm.

11) The method according to any one of items 1 to 10, wherein a susceptor on which the substrate is placed has a temperature of 200° C. or higher in steps (i) through (iii).

12) The method according to any one of items 1 through 10, further comprising determining a priority area of cleaning inside the reactor prior to step (ii).

13) The method according to item 11, wherein step (iii) comprises controlling pressure inside the reactor according to the priority area of cleaning.

14) The method according to item 11 or 12, wherein step (iii) comprises controlling pressure inside the reactor at about no control state (0 Pa) to about 400 Pa.

15) The method according to item 2, wherein step (ii) is conducted in the reactor.

16) The method according to any one of items 1-16, wherein the carbon-based polymer film in step (i) is a carbon polymer film formed by:

vaporizing a hydrocarbon-containing liquid monomer (C_{α}H_{β}X_{γ}, wherein α and β are natural numbers of 5 or more; γ is an integer including zero; X is O, N or F) having a boiling point of about 20° C. to about 350° C. which has no benzene structure;

introducing said vaporized gas into a CVD reaction chamber inside which a substrate is placed; and

forming a hydrocarbon-containing polymer film on said substrate by plasma polymerization of said gas.

17) A method of self-cleaning a plasma reactor using a cleaning gas containing oxygen gas, nitrogen tri-fluoride gas, and inert gas, comprising: (i) forming a carbon-based film on the substrate in the reactor a pre-selected number of times;

(ii) exciting oxygen gas, nitrogen tri-fluoride gas, and inert gas to generate a plasma for cleaning; (iii) cleaning an inside of the reactor with the plasma to remove particles accumulated during step (i) on the inside of the reactor; and

(iv) repeating steps (i)-(iii) a pre-selected number of times.

18) The method according to item 17, wherein step (ii) is conducted in the reactor and/or a remote plasma unit.

It will be understood by those of skill in the art that numerous and various modifications can be made without departing from the spirit of the present invention. Therefore, it should be clearly understood that the forms of the present invention are illustrative only and are not intended to limit the scope of the present invention.

What is claimed is:

1. A method of continuously forming carbon-based films on substrates, comprising:
(i) forming a carbon-based film on a substrate in a reactor a pre-selected number of times;
(ii) exciting an inert gas, an oxygen gas, and a nitrogen fluoride gas to generate a plasma for cleaning;
(iii) cleaning an inside of the reactor with the plasma after step (i) to remove particles accumulated during step (i) on the inside of the reactor.

2. The method according to claim 1, wherein step (ii) comprises supplying the inert gas, the oxygen gas, and the nitrogen fluoride gas in a remote plasma unit.

3. The method according to claim 1, wherein step (ii) is conducted in the reactor.

4. The method according to claim 1, wherein in step (ii), the nitrogen fluoride gas is nitrogen tri-fluoride gas.

5. The method according to claim 1, wherein the inert gas is Ar gas.

6. The method according to claim 1, wherein the oxygen gas is O₂ gas.

7. The method according to claim 1, wherein in step (ii), a flow rate of the oxygen gas is set at 100 to 5,000 sccm.

8. The method according to claim 1, wherein in step (ii), a flow rate of the inert gas is set at 1,000 to 10,000 sccm.

9. The method according to claim 4, wherein in step (ii), a flow rate of the nitrogen tri-fluoride gas is set at 5 to 1000 sccm.

10. The method according to claim 4, wherein in step (ii), a flow rate of the nitrogen tri-fluoride gas is set at 10 to 500 sccm.

11. The method according to claim 1, wherein in step (ii), a flow rate of the nitrogen fluoride gas is set at a value which is less than 5% of total flow rates of the inert gas, the oxygen gas, and the nitrogen fluoride gas.

12. The method according to claim 1, wherein in steps (i) to (iii), a susceptor on which the substrate is placed is controlled at a temperature of about 200° C. or higher.

13. The method according to claim 1, further comprising determining a priority area of cleaning inside the reactor prior to step (iii).

14. The method according to claim 13, wherein step (iii) comprises controlling pressure inside the reactor according to the priority area of cleaning.

15. The method according to claim 14, wherein step (iii) comprises controlling pressure inside the reactor in a range of about no control state to about 500 Pa.

16. The method according to claim 13, wherein step (iii) comprises controlling a gap between an upper electrode and a lower electrode according to the priority area of cleaning.

17. The method according to claim 1, wherein the carbon-based polymer film in step (i) is a carbon polymer film formed by:
vaporizing a hydrocarbon-containing liquid monomer (C_{α}H_{β}X_{γ}, wherein α and β are natural numbers of 5 or more; γ is an integer including zero; X is O, N or F) having a boiling point of about 20° C. to about 350° C. which is not substituted by a vinyl group or an acetylene group;
introducing said vaporized gas into a CVD reaction chamber inside which a substrate is placed; and
forming a hydrocarbon-containing polymer film on said substrate by plasma polymerization of said gas.

18. A method of continuously forming carbon-based films on substrates, comprising:
(i) forming a carbon-based film on a substrate in a reactor a pre-selected number of times;
(ii) exciting a cleaning gas comprised of an oxygen-containing gas and a fluorine-containing gas to generate a plasma for cleaning, wherein a flow ratio of the fluorine-containing gas to the oxygen-containing gas is 3/100 to 15/100; and
(iii) cleaning an inside of the reactor with the plasma after step (i) to remove particles accumulated during step (i) on the inside of the reactor.

19. The method according to claim 18, wherein the fluorine-containing gas is nitrogen tri-fluoride.

20. The method according to claim 18, wherein in step (ii), an inert gas is added in an amount greater than the oxygen gas.

21. A method of continuously forming carbon-based films on substrates, comprising:
(i) forming a carbon-based film on a substrate in a reactor a pre-selected number of times;
(ii) exciting a cleaning gas comprised of an oxygen-containing gas and a fluorine-containing gas to generate a plasma for cleaning, wherein the cleaning gas contains the fluorine-containing gas in an amount effective to increase a cleaning rate 40-fold or higher when using the plasma for cleaning an inside of the reactor as compared with a cleaning rate obtained without the fluorine-containing gas; and
(iii) cleaning an inside of the reactor with the plasma after step (i) to remove particles accumulated during step (i) on the inside of the reactor.

22. The method according to claim 21, wherein the fluorine-containing gas is constituted solely by nitrogen tri-fluoride.

23. The method according to claim 21, wherein the oxygen-containing gas is constituted solely by oxygen.

24. The method according to claim 21, wherein in step (ii), argon is added in an amount greater than the oxygen gas

25. A processing reactor apparatus programmed to conduct the method of claim 21.
